(19) United States
(12) Patent Application Publication
(10) Pub. No.: US 2012/0039072 A1
(43) Pub. Date: Feb. 16, 2012

(54) Luminous Means and Projector Comprising at Least One Luminous Means of this Type

(76) Inventors: Alfred Lell, Maxhutte-Haidhof (DE); Sönke Tautz, Tegernheim (DE); Uwe Strauss, Bad Abbach (DE); Martin Rudolf Behringer, Regensburg (DE); Stefanie Brüninghoff, Zeitlarn (DE); Dimitri Dini, Regensburg (DE); Dominik Eisert, Regensburg (DE); Christoph Eichler, Tegernheim (DE)

(21) Appl. No.: 13/141,078

(22) PCT Filed: Oct. 19, 2009
(86) PCT No.: PCT/DE2009/001448

§ 371 Date: Sep. 12, 2011

(30) Foreign Application Priority Data
Dec. 18, 2008 (DE) 10 2008 063 634.7

(51) Int. Cl. H01S 5/06; H01S 5/40

(52) U.S. Cl. 362/227; 362/259

(57) ABSTRACT

In at least one embodiment of the light source (1), the latter includes at least one semiconductor laser (2), which is designed to emit a primary radiation (P) of a wavelength of between 360 nm and 485 nm inclusive. Furthermore, the light source (1) comprises at least one conversion medium (3), which is arranged downstream of the semiconductor laser (2) and is designed to convert at least part of the primary radiation (P) into secondary radiation (S) of a different, greater wavelength than the primary radiation (P). The radiation (R) emitted by the light source (1) here displays an optical coherence length which amounts to at most 50 μm.

The invention relates to a light source. It further relates to a projector with at least one such light source.

An object to be achieved is to provide a high luminance light source. Another object which is to be achieved is to provide a projector with at least one such light source.

According to at least one embodiment of the light source, the latter comprises at least one optoelectronic semiconductor chip. The semiconductor chip is designed to generate electromagnetic radiation in the ultraviolet or visible spectral range. The semiconductor chip may comprise a light-emitting diode or a semiconductor laser.

According to at least one embodiment of the light source, the latter comprises at least one semiconductor laser, which is designed to emit primary radiation of a wavelength of between 360 nm and 485 nm inclusive, in particular between 380 nm and 460 nm inclusive. In other words the primary radiation is generated by way of at least one semiconductor laser. The light source may in particular have no light-emitting diodes, such that the primary radiation is generated solely by semiconductor lasers.

According to at least one embodiment of the light source, the latter comprises at least one conversion medium. The conversion medium is arranged downstream of the semiconductor laser in the beam direction of the primary radiation and is designed to convert at least part of the primary radiation into secondary radiation. The secondary radiation has a different, preferably greater wavelength than the primary radiation.

According to at least one embodiment of the light source, radiation emitted by the light source is formed of the secondary radiation or of a mixture of secondary radiation and primary radiation. If the radiation emitted by the light source is mixed radiation, the radiation is preferably already mixed when it leaves the light source. The radiation emitted by the light source is in particular homogeneous over the entire beam cross-section of the radiation. In other words, a chromaticity coordinate, also referred to as colour location, of the radiation emitted by the light source deviates over the entire beam cross-section by at most 0.05 units, in particular by at most 0.025 units, in the standard chromaticity diagram from a mean formed over the entire beam cross-section.

According to at least one embodiment of the light source, the radiation emitted by the light source has an optical coherence length which amounts to at most 50 μm. The optical coherence length preferably amounts to at most 10 μm, in particular at most 2.5 μm. In other words, the radiation emitted by the light source is incoherent radiation, which is not capable of interference. In this way, effects such as speckle patterns, which may occur when coherent radiation is used for example for projection purposes, may be avoided.

Use of the conversion medium in the light source is based, inter alia, on the following concept: the primary radiation of the light source is generated by a semiconductor laser, which has a comparatively long coherence length and is capable of interference. By using the conversion medium, which in particular contains a plurality of mutually independent colour centres or lighting points, also referred to as pixels, incoherent secondary radiation is generated. The secondary radiation is incoherent in particular because the plurality of for example colour centres absorb the primary radiation decoupled from one another and emit the converted radiation, or secondary radiation, with a time delay and not in a mutually correlated manner. There is also not generally a spatially defined relationship between individual colour centres, for example. Therefore, the secondary radiation emitted by the individual colour centres, for example, does not exhibit a fixed or defined phase relationship to secondary radiation emitted by adjacent colour centres. In addition, the secondary radiation has a comparatively large spectral width compared to primary radiation. In this way, the coherence length is likewise reduced.

According to at least one embodiment of the light source, the optical coherence length is less than or equal to the quotient of the square of an average wavelength of the radiation and a spectral bandwidth of the radiation emitted by the light source, multiplied by a constant factor:

L≦kλ₀²/Δλ

L here denotes the optical coherence length of the radiation emitted by the light source, λ₀ the average wavelength of the radiation emitted by the light source and Δλ the spectral width thereof. In particular, the optical coherence length amounts to at most 90%, in particular to at most 75% of the value obtained using the above formula.

By way of the above-stated formula, the optical coherence length of radiation may be estimated, as a function of the bandwidth and the average wavelength of the radiation. The factor k, which is a real number of the order of magnitude of 1, is a function of an envelope of a spectrum of the radiation. The radiation emitted by the light source may in other words have a shorter coherence length than is obtained according to the above formula for radiation of a corresponding spectral width. The optical coherence length may thus in particular be shorter than for a spectrally broadband light source, which is based on a laser for example.

If the radiation emitted by the light source is mixed radiation obtained by mixing secondary radiation and primary radiation, the radiation in this case also has a short coherence length, since the phase relationship and thus the interference capability is destroyed by mixing primary radiation and secondary radiation.

The optical coherence length may be determined for example using an interferometer. The interferometer for example comprises two interferometer arms, which display a variable difference in length relative to one another. If the radiation is directed over the two arms and then superimposed, an interference pattern appears as a function of the length difference between the arms. The length of the arm length difference after which an interference pattern no longer appears is then the optical coherence length.

In at least one embodiment of the light source, the latter includes at least one semiconductor laser, which is designed to emit primary radiation of a wavelength of between 360 nm and 485 nm inclusive. Furthermore, the light source comprises at least one conversion medium, which is arranged downstream of the semiconductor laser and is designed to convert at least part of the primary radiation into secondary radiation of a different, greater wavelength than the primary radiation. The radiation emitted by the light source here displays an optical coherence length which amounts to at most 50 μm.

The primary radiation may be efficiently shaped, in particular focused, by means of the semiconductor laser which emits coherent radiation. In this way high power densities of the primary radiation may be achieved in the conversion medium. At the same time, a high luminance of the secondary radiation and virtually punctiform emission of the secondary radiation may also be achieved. As a result of the short optical coherence length, speckle patterns may for example be avoided for instance in the case of projection of the radiation emitted by the light source.

According to at least one embodiment of the light source, the conversion medium comprises no or virtually no organic material. For example the conversion medium contains a matrix material of a glass or a sintered ceramic. Luminescent material particles or pigments are for example embedded into the matrix material. Organic materials are often only resistant to a limited extent to photochemical damage, which may occur in the case in particular of high primary radiation luminances. If the conversion medium does not comprise any organic material, a high luminance may be achieved for the secondary radiation.

According to at least one embodiment of the light source, the at least one conversion medium comprises at least one cerium- or europium-doped luminescent material.

According to at least one embodiment of the light source, the at least one conversion medium has a concentration of colour centres or pixels which amounts to at least 10⁷/μm³, preferably at least 5*10⁷/μm³, in particular at least 10⁸/μm³. The colour centres or pixels are preferably distributed randomly in the conversion medium, such that there is no fixed or regular, lattice-like spatial relationship between mutually adjacent colour centres or pixels, and emit the secondary radiation mutually independently. As a result of such a high density of the mutually independently emitting colour centres or pixels, a particularly short optical coherence length of the secondary radiation may be obtained.

According to at least one embodiment of the light source, the primary radiation at least the same number of colour centres or pixels in the conversion medium as corresponds to the product of the vacuum light velocity with a decay time of the conversion medium, divided by the coherence length:

N≧(cT)/L

L here denotes the optical coherence length, c the vacuum light velocity, T the in particular exponential decay time of the conversion medium and N the number of colour centres or pixels excited by the primary radiation. N is preferably greater than or equal to ten times, in particular greater than or equal to fifty times, the right-hand side of the above formula.

In other words, the greater is the decay time of the conversion medium, the more colour centres or pixels are excited. For example N is greater than 10⁶, in particular greater than 10⁸. The large number of excited colour centres or pixels, relative to the decay time, may allow a short coherence length.

According to at least one embodiment of the light source, the luminance of the secondary radiation on exit from the conversion medium amounts at least in places to at least 1 kW/cm². The luminance preferably exceeds 10 kW/cm², particularly preferably 100 kW/cm², in particular 1000 kW/cm².

According to at least one embodiment of the light source, the latter comprises a thermally conductive first carrier. The at least one conversion medium is mounted at least indirectly, in particular directly, on the first carrier. Preferably, the material of the conversion medium is in direct contact with a material of the first carrier. In this way, efficient thermal coupling and efficient dissipation of heat from the conversion medium may be ensured by way of the first carrier.

According to at least one embodiment of the light source, the first carrier is transparent or reflective at least with regard to part of the secondary radiation. Transparent here means that at least 90%, preferably at least 95%, of the secondary radiation passes through the first carrier without experiencing scatter or absorption. Reflective means that at least 90%, preferably at least 95%, of the secondary radiation impinging on the first carrier is reflected thereat.

According to at least one embodiment of the light source, the first carrier is transparent or impermeable to the primary radiation. Transparent means that at least 90%, preferably at least 95%, of the primary radiation penetrates the first carrier without being absorbed or scattered. Impermeable means that at most 100 of the primary radiation may penetrate the first carrier.

According to at least one embodiment of the light source, the latter comprises at least one collimating optical system. This collimating optical system is arranged downstream of the conversion medium in the beam direction of the primary and/or secondary radiation. The collimating optical system may reduce and/or adjust the divergence angle of the secondary radiation generated by conversion. The collimating optical system may be an achromat.

According to at least one embodiment of the light source, after passage through the collimating optical system the divergence angle of the secondary radiation amounts at least in places to at most 10°, preferably at most 5°, in particular at most 1.5°. Slight divergence of the secondary radiation simplifies beam guidance of the secondary radiation and beam shaping thereof, for example in downstream optical elements.

According to at least one embodiment of the light source, the at least one collimating optical system is designed to shape the secondary radiation into a parallel pencil of rays. Parallel may here mean that the divergence angle of the pencil of rays amounts to at most 1°, preferably to at most 0.5°. This is possible because the secondary radiation is generated with an elevated luminance in a small spatial area.

According to at least one embodiment of the light source, the latter comprises at least one light spot, irradiated by the primary radiation, of the conversion medium. The light spot is here in particular that preferably continuous area of the conversion medium via which the primary radiation penetrates into the conversion medium.

According to at least one embodiment of the light source, the conversion medium is roughened at a light inlet face, in particular in the region of the light spot, and/or at a light outlet face. This improves in- and outcoupling of light into or out of the conversion medium. Light scattering also takes place at the light inlet face and the light outlet face, by means of which the coherence length of the radiation may be reduced.

According to at least one embodiment of the light source, the at least one light spot has an area of at most 0.5 mm², preferably of at most 0.1 mm². For example the area of the light spot lies in the range between 10 μm² and 10000 μm² inclusive, in particular between 100 μm² and 2000 μm² inclusive. In other words, the secondary radiation is generated in a punctiform region. If a radiation entrance face for the primary radiation of the conversion medium is roughened, the area of the light spot should be understood to mean that area which results from a projection of the area actually illuminated by the primary radiation onto an in particular notional plane perpendicular to a beam axis of the primary radiation.

According to at least one embodiment of the light source, the latter comprises at least two semiconductor lasers, which irradiate the same light spot. In other words, within the bounds of manufacturing and adjusting accuracy, the at least two semiconductor lasers irradiate the same point of the conversion medium. By using two semiconductor lasers to illuminate the same light spot, particularly high luminances may be achieved relative to the secondary radiation. If the conversion medium is a mixture of at least two different luminescent materials, the semiconductor lasers irradiating the light spot may have different primary radiation wavelengths, so as to ensure particularly efficient generation of the secondary radiation.

According to at least one embodiment of the light source, the latter comprises at least one second carrier in addition to the first carrier. The conversion medium is located in each case in at least indirect contact with the carriers, in particular in direct contact.

According to at least one embodiment of the light source, the conversion medium is located between the first carrier and the second carrier. In particular, the material of the conversion medium may be in direct contact with the materials in each case of the first and second carriers.

According to at least one embodiment of the light source, the primary radiation passes through at least one of the carriers. In particular, the primary radiation may pass through both the first and second carriers.

According to at least one embodiment of the light source, the conversion medium is applied to a major side of the first carrier. This major side is reflective relative to the secondary radiation or provided with a coating with a reflective action relative to the secondary radiation, such that at least 90%, in particular at least 95%, of the secondary radiation is reflected at the major side. Likewise, the major side is preferably reflective relative to the primary radiation or provided with a reflective coating. In other words, conversion does not proceed as a result of transmission through the conversion medium, but rather by way of reflection at the first carrier. In addition, a beam path, a beam axis or a main beam direction of the primary and/or secondary radiation undergoes a change in direction at the major side of the first carrier.

According to at least one embodiment of the light source, the latter comprises at least three semiconductor lasers. Two of the semiconductor lasers illuminate at least two different light spots of the conversion medium. The radiation emitted by the light source comprises red, green and blue light. For example, two of the semiconductor lasers are used to generate red and green light from blue or ultraviolet light of the primary radiation at different light spots by way of conversion. The blue light may likewise be generated by way of conversion or indeed formed by the primary radiation of one of the three semiconductor lasers. The radiation emitted by the light source is thus for example a mixture of red, green and blue light in each case generated in particular by means of conversion or indeed a mixture of for instance red and green light of the secondary radiation and blue light of the primary radiation. At the light spots illuminated by the semiconductor lasers, mutually different conversion media or mixtures of conversion media may be used, such that for example one of the light spots emits only red secondary radiation and another of the light spots emits only green secondary radiation.

According to at least one embodiment of the light source, the red, green and blue light may be generated mutually independently. This may be achieved in that light spots of the conversion medium are irradiated by different semiconductor lasers and the semiconductor lasers may be variably adjusted with regard to their time domain intensity. Different intensities may thus be set at different times, in particular mutually independently. It is likewise possible for a component to be located between the at least one semiconductor laser and the conversion medium which may modulate the intensity of the primary radiation.

According to at least one embodiment of the light source, the red, green and blue light pass jointly along at least part of the beam path. In other words, red, green and blue light are guided parallel to one another and, within the bounds of manufacturing tolerances, have identical beam axes, at least along part of the beam path. Preferably, the red, green and blue light are in each case parallel pencils of rays.

According to at least one embodiment of the light source, the latter comprises at least one modulator, which is located in the beam path of the secondary radiation and which is designed to adjust the intensity of the secondary radiation by way of transmission or reflection. The modulator may be a liquid crystal unit or a Spatial Light Modulator, SLM for short. It is likewise possible for the modulator to take the form of at least one Pockels cell or Kerr cell. If the modulator has a transmissive action, the intensity of the secondary radiation passing through the modulator may thus be adjusted as a function of time. If the modulator has a reflective action, a reflectance or a reflection direction may be varied over time.

According to at least one embodiment of the light source, an intensity and/or a colour location of the radiation emitted by the light source may be tuned to a frequency of at least 10 MHz, in particular of at least 25 MHz. Tuning may be effected for example by means of a digital micromirror device, or DMD for short. Such high tuning rates allow use of the light source for example in a projector, in particular in a “Flying Spot Projector”.

According to at least one embodiment of the light source, the first carrier may be mounted so as to be mechanically mobile and comprises at least two regions which are provided with mutually different conversion media. If the carrier is displaced, the primary radiation irradiates different regions, for example, and thus different conversion media. In particular, the first carrier is mobile in one direction, especially only in a direction perpendicular to a beam axis of the primary radiation, such that moving the first carrier results for example in no or no significant change to the beam path of the primary radiation and/or the secondary radiation. In this way, the colour location of the secondary radiation may be set by positioning or moving the first carrier.

According to at least one embodiment of the light source, the first carrier, to which the conversion medium is applied, is mounted so as to be mechanically movable. Movement of the carrier, in a direction perpendicular to the beam axis of the primary radiation, proceeds at least temporarily at a speed of at least 1 cm/s, in particular of at least 5 cm/s. In this way, thermal loading of the conversion medium may be limited.

According to at least one embodiment of the light source, the first and/or the second carrier exhibits a thermal conductivity of at least 40 W/(m K), preferably of at least 120 W/(m K), in particular of at least 300 W/(m K). For example, the first carrier is made of silicon carbide, sapphire, diamond or an in particular transparent ceramic such as for example AlN.

According to at least one embodiment of the light source, the latter comprises at least one pinhole, also referred to as perforated diaphragm, which is arranged downstream of the conversion medium. The perforated diaphragm may prevent radiation from scattering on leaving the light source, such that radiation emitted by the light source is emitted in a defined, small spatial area and the beam may be shaped for instance in an optical element arranged downstream of the light source.

According to at least one embodiment of the light source, a region on the major face of the first carrier, on which the conversion medium is mounted, has a diameter which corresponds to at most three times the average diameter of the light spot, in particular at most twice, preferably at most 1.2 times, the average diameter of the light spot.

According to at least one embodiment of the light source, the latter comprises a deflection unit and/or an imaging unit, which is located in or on the beam path. The deflection unit may take the form of a spatial light modulator. The imaging unit may, for example, be a liquid crystal mask.

According to at least one embodiment of the light source, the conversion medium is thermally decoupled from the semiconductor laser, i.e. no or no significant thermal crosstalk occurs from the conversion medium to the semiconductor laser and vice versa. This allows particularly stable operation of the light source with regard to intensity and colour location.

According to at least one embodiment of the light source, the latter comprises a surface-mountable housing, in which the at least one semiconductor laser is mounted. Likewise, the at least one conversion medium may be located partially or completely in the housing. The housing is configured for example according to document US 2007/0091945 A1, the disclosure content of which regarding the housing described therein and the method described therein is hereby included by reference. The housing may likewise be a housing according to document US 2008/0116551 A1, the disclosure content of which regarding the component described therein and the method described therein for producing such a component is hereby included by reference.

According to at least one embodiment of the light source, the housing takes the form of a “Transistor Single Outline housing”, TO housing for short.

According to at least one embodiment of the light source, the volume of the entire light source is in the range between 0.01 mm³ and 60 mm³ inclusive, in particular between 0.4 mm³ and 8 mm³ inclusive.

The invention further relates to a projector. The projector comprises at least one light source according to any one of the preceding claims and at least one deflection unit and/or at least one imaging unit.

Some of the fields of application in which light sources described herein may be used are for instance the backlighting of displays or display means. Furthermore, the light sources described herein may also be used in lighting devices for projection purposes, in floodlights or spotlights or for general lighting.

A light source described herein and a projector described herein will be explained in greater detail below with reference to the drawings and with the aid of exemplary embodiments. Elements which are the same in the individual figures are indicated with the same reference numerals. The relationships between the elements are not shown to scale, however, but rather individual elements may be shown exaggeratedly large to assist in understanding.

In the drawings:

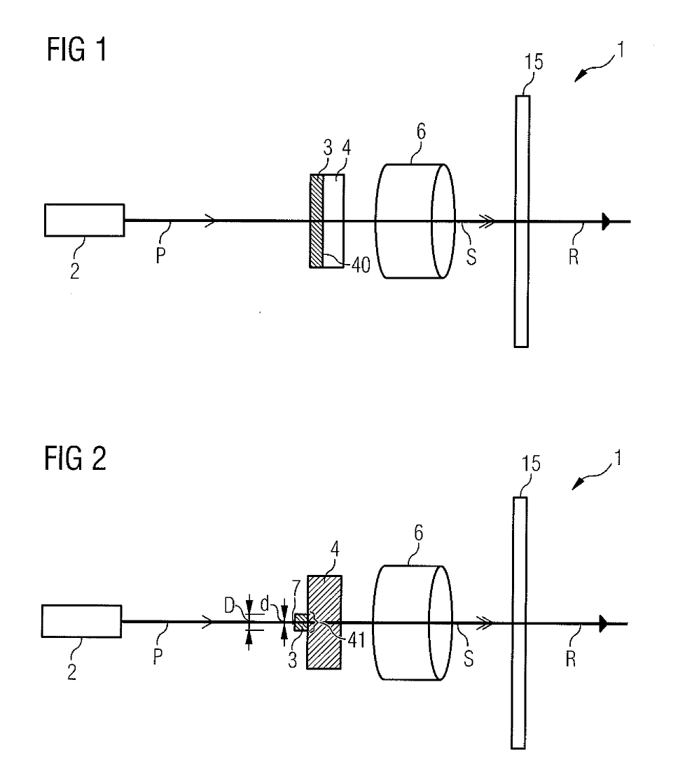

FIGS. 1 to 5 are schematic representations of exemplary embodiments of light sources described herein with a first carrier,

FIGS. 6 to 8 are schematic representations of exemplary embodiments of light sources described herein with a second carrier,

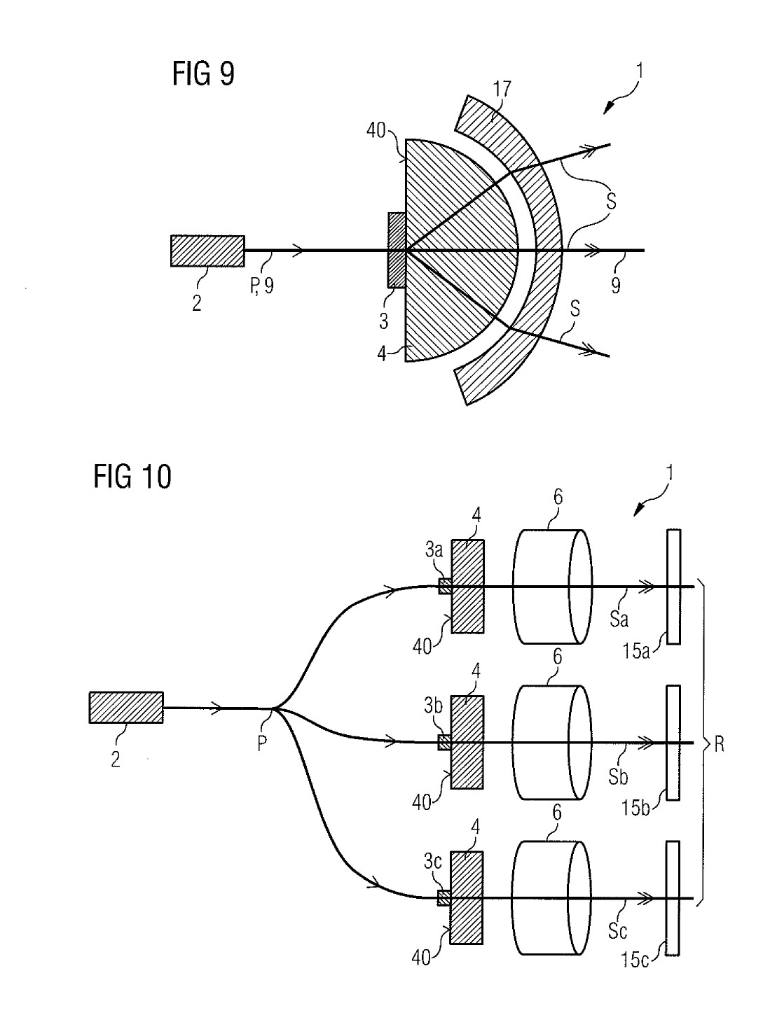

FIG. 9 is a schematic representation of an exemplary embodiment of a light source described herein with a first carrier configured as an optical system,

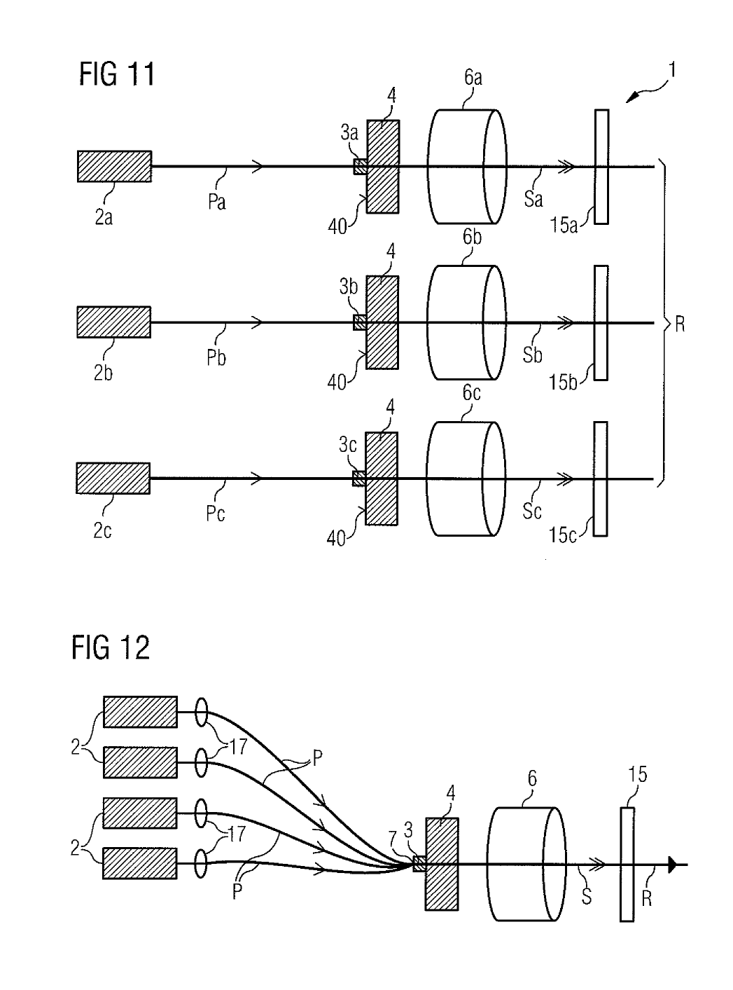

FIGS. 10 and 11 are schematic representations of exemplary embodiments of light sources described herein with different conversion media,

FIG. 12 is a schematic representation of an exemplary embodiment of a light source described herein, in which a plurality of semiconductor lasers irradiate one light spot,

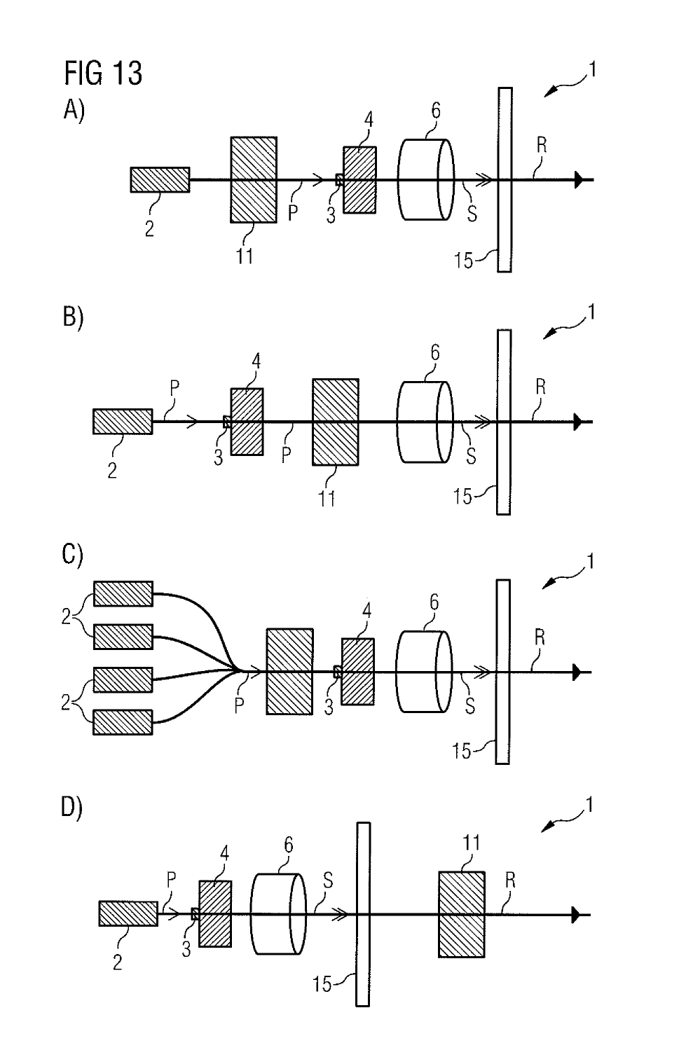

FIGS. 13 to 15 are schematic representations of further exemplary embodiments of light sources described herein,

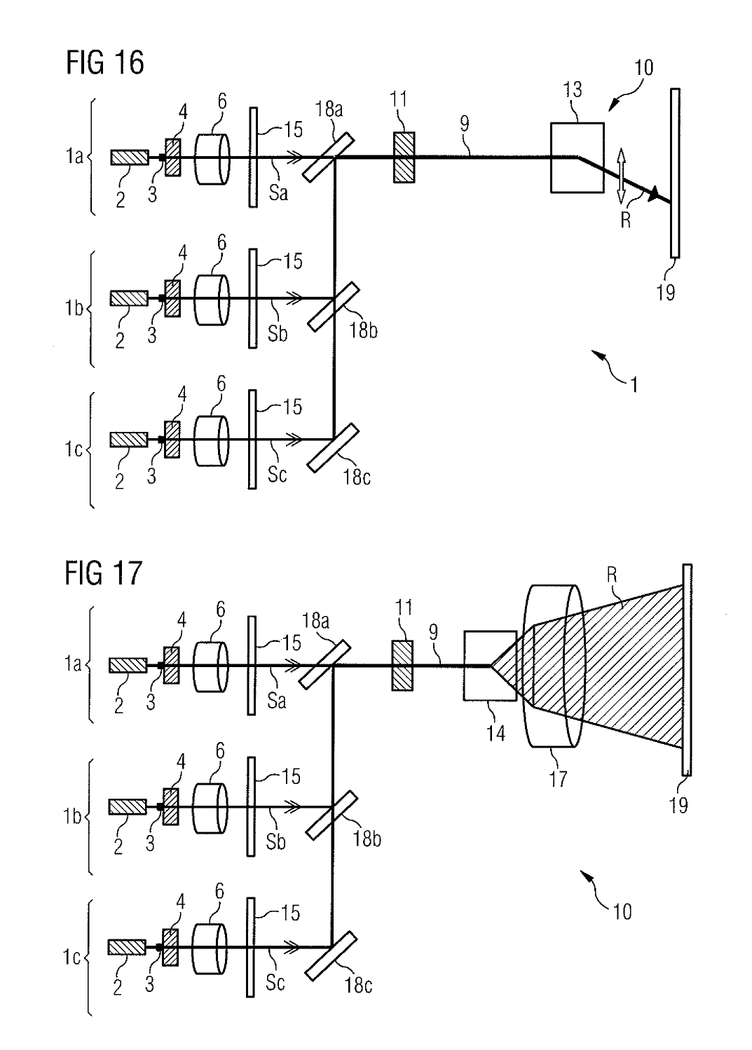

FIGS. 16 and 17 are schematic representations of exemplary embodiments of projectors described herein,

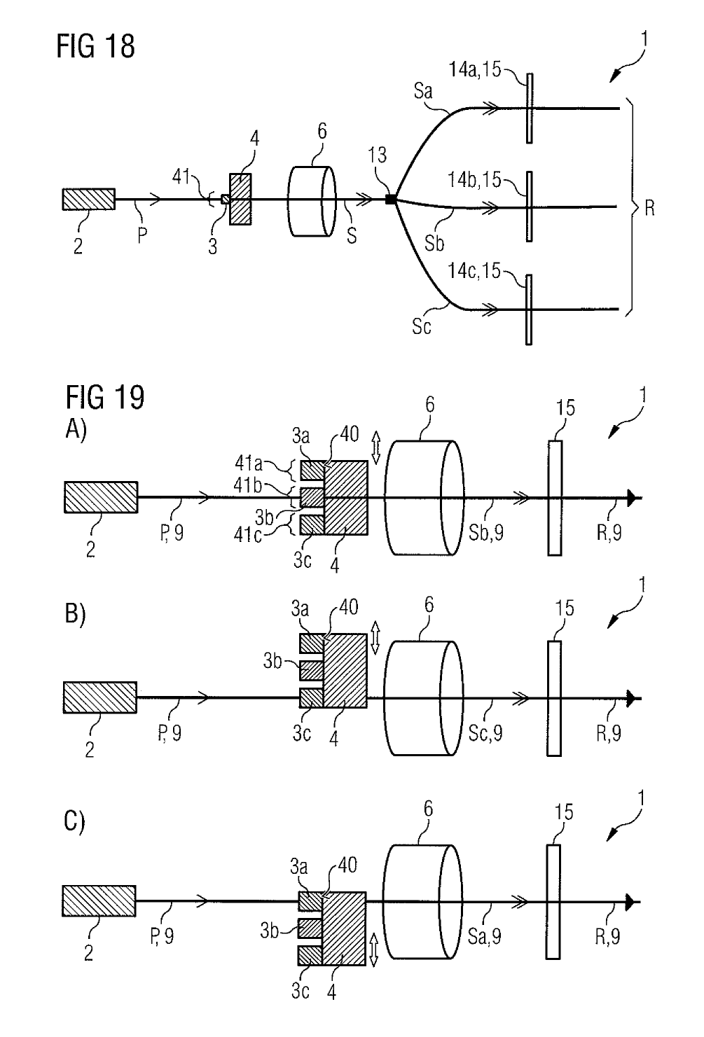

FIGS. 18 and 19 are schematic representations of exemplary embodiments of further light sources described herein, and

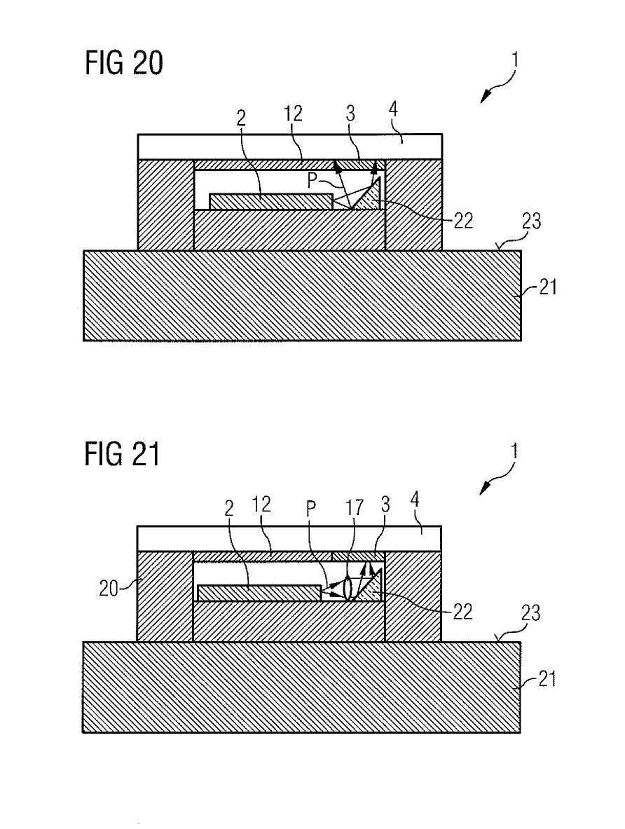

FIGS. 20 to 29 are schematic representations of exemplary embodiments of light sources described herein with housings.

FIG. 1 shows an exemplary embodiment of a light source 1. A semiconductor laser 2 emits primary radiation P, symbolised by a line with a single arrow head. The primary radiation P has a wavelength of between 370 nm and 400 nm. A conversion medium 3, which is applied in a layer to a major side 40 of a first carrier 4 is arranged downstream of the semiconductor laser 2 in the beam direction of the primary radiation P. The layer thickness of the conversion medium 3, in a direction perpendicular to the major side 40, lies between around 1 μm and 1000 μm, preferably between 3 μm and 300 μm inclusive. The conversion medium 3 comprises at least one cerium- and/or europium-doped luminescent material.

The primary radiation P is absorbed by the conversion medium 3 and converted into longer-wave secondary radiation S. A main beam direction of the secondary radiation S is symbolised by a line bearing a double arrow head. The primary radiation P, which is laser radiation, has a very long optical coherence length compared with the secondary radiation S. By using the conversion medium 3 with a plurality of colour centres or pixels, the coherence length is reduced significantly and interference, caused for example by speckle patterns, may be prevented.

A collimating optical system 6 is mounted a short distance downstream of the conversion medium 3 in the beam direction. The secondary radiation S arriving at the collimating optical system 6 is shaped into an approximately parallel pencil of rays. The collimating optical system 6 may for example comprise an achromatic lens.

A filter 15 is optionally arranged downstream of the collimating optical system 6 in the beam direction. The filter 15 may be a colour filter and/or a polarisation filter. The filter 15 may filter out certain spectral components. In particular, the filter 15 may be impermeable to the primary radiation P. In this case radiation R emitted by the light source, symbolised by a line with a solid arrow head, is only at least part of the secondary radiation S.

In the exemplary embodiment according to FIG. 2, the conversion medium 3 is applied to the major side 40 of the first carrier 4 over only a small region 41 of diameter D. A light spot 7 of a diameter d is defined by that area irradiated by the primary radiation P on a side of the conversion medium 3 facing the semiconductor laser 2. A ratio D/d of the diameter is of the order of magnitude of 1. The light spot 7 comprises an area between 10 μm² and 10,000 μm² inclusive. The light spot 7 may be applied in a patterned manner to the carrier 4 for instance by a screen printing method or indeed by means of a lithographic process. In order to achieve such a small light spot 7 with the primary radiation P, a lens, not shown in FIG. 2, may be mounted between the semiconductor laser 2 and the conversion medium 3.

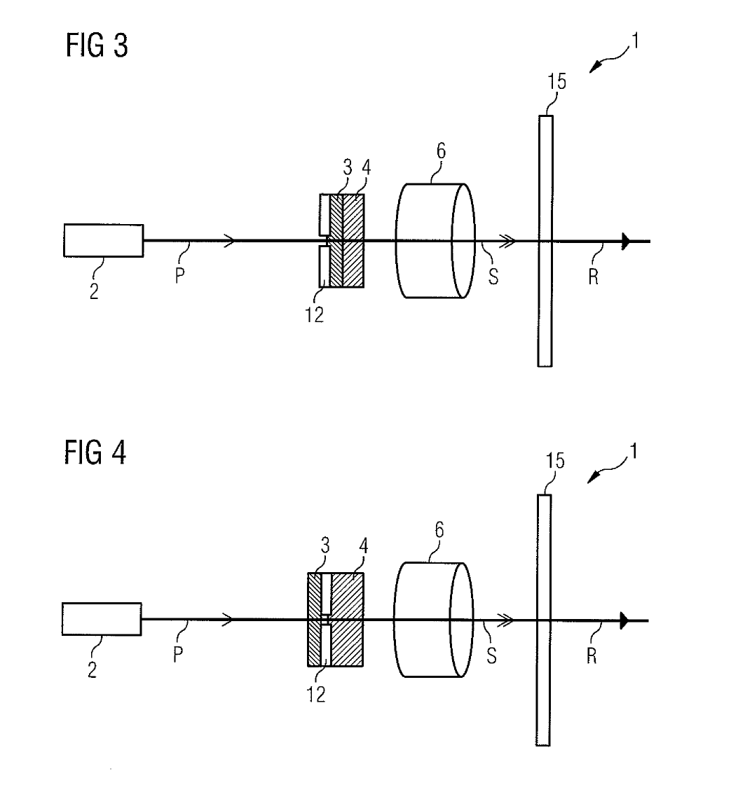

According to FIG. 3, the light source 1 comprises a pinhole, also referred to as perforated diaphragm 12. The perforated diaphragm 12 is arranged on a major side, facing the semiconductor laser 2, of the conversion medium 3 applied extensively to the carrier 4. The perforated diaphragm is formed for example by metal coating with gold, silver, platinum, palladium, titanium, chromium or another metal, which may be highly reflective relative to the secondary radiation. The perforated diaphragm 12 may likewise be made from a layer sequence, for example a dielectric layer sequence, in the form of a Bragg mirror. In this case the perforated diaphragm 12 comprises a layer sequence of for instance aluminium oxide, silicon oxide, silicon nitride, tantalum oxide, titanium oxide, niobium oxide and/or neodymium oxide. The individual layers each preferably have an optical thickness of a quarter of a wavelength of the secondary radiation S. It is also possible for the material of the perforated diaphragm 12 to have an absorbent action and for example to be carbon black.

The power of the secondary radiation S amounts to a few tens of mW to a few 100 mW, but may also amount to a few W. To dissipate the heat resulting from conversion in the conversion medium 3, the carrier 4 is preferably made of a material with elevated thermal conductivity, for example sapphire or silicon carbide. The carrier 4 may also be made of a glass or a ceramic. Further materials may be added to the carrier 4 to increase thermal conductivity.

In the exemplary embodiment according to FIG. 4 the perforated diaphragm 12 is located between the conversion medium 3 and the carrier 4. The material of the perforated diaphragm 12 may serve to improve adhesion between the conversion medium 3 and the carrier 4.

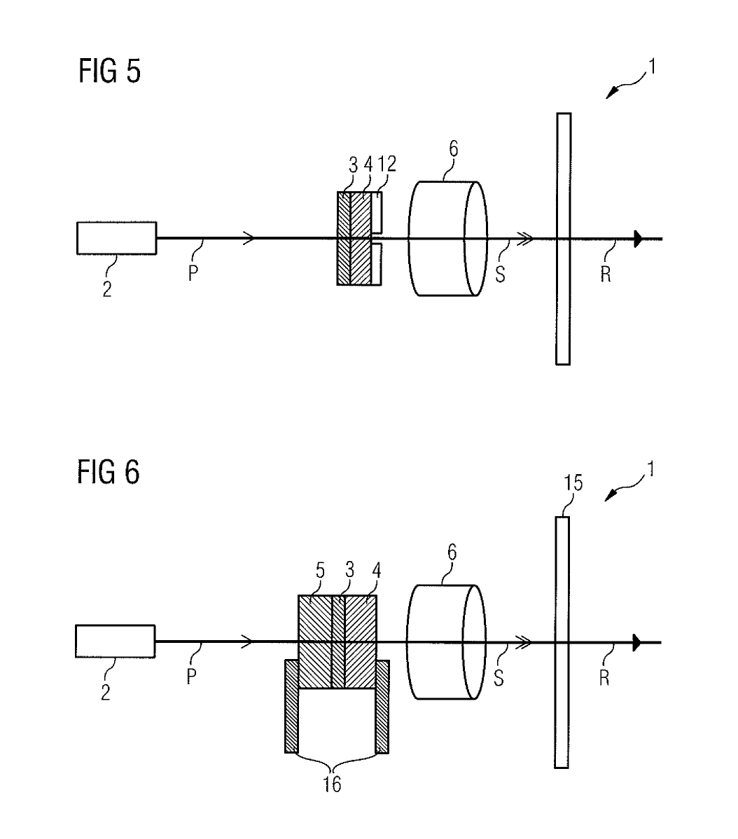

FIG. 5 shows that the perforated diaphragm 12 is located on a major side of the carrier 4 remote from the conversion medium 3. The carrier 4 is transparent relative to the wavelength of the secondary radiation S and preferably comprises a thickness in the range between 25 μm and 500 μm inclusive.

In FIG. 6 the light source 1 comprises a second carrier 5. The conversion medium 3 is located between the first carrier 4 and the second carrier 5 and is in each case in direct contact with the materials of the carrier 4, 5. In addition, the light source 1 comprises two holders 16, which are preferably made of a metal and improve heat dissipation from the carriers 4, 5.

The first carrier 4 is transparent, relative both to the primary radiation P and to the secondary radiation S. The second carrier 5 is transparent relative to the primary radiation P and may have a reflective action relative to the secondary radiation S. Configuring the carriers 4, 5 in this way makes it possible for the radiation R emitted by the light source 1 to consist of a mixture of primary radiation P and secondary radiation S.

The conversion medium 3 may be a phosphorus layer applied to the carrier 4 by screen printing. The second carrier 5 is then adhesively bonded to the conversion medium 3, for example. The conversion medium 3 contains or consists for example of a crystalline and/or ceramic material, into which colour centres have been introduced in a randomly distributed manner. If the conversion medium is made from a crystalline substance, a thin wafer constituting the conversion medium 3 is for example sawn out of a larger crystal. This wafer of conversion medium 3 may then be attached to the first carrier 4, for example, by means of a thin adhesive layer. The adhesive here preferably has a high thermal conductivity and radiation resistance.

It is alternatively possible to attach the conversion medium 3 to the carriers 4, 5 by a wafer bonding method. In this case, a thin silicon oxide layer is applied over the major faces of the conversion medium 3, and to the major sides of the carriers 4, 5. Pressure and heat then bring about a permanent bond between conversion medium 3 and carriers 4, 5 by way of the silicon dioxide layers. The silicon dioxide layers are not shown in FIG. 6.

A further possible way of bonding the first carrier 4 and the conversion medium 3 is the synthesis of ceramic, transparent and converter-containing layers, which comprise the conversion medium 3. In this case, the starting materials for the transparent layer or the first carrier 4, i.e. for example aluminium oxide powder, are spread as a thick layer. A starting material for the conversion medium 3 is then applied to this layer in a small thickness. A single ceramic layer may then arise by means of subsequent sintering, such that in this case the first carrier 4 and the conversion medium 3 may be constructed in one piece.

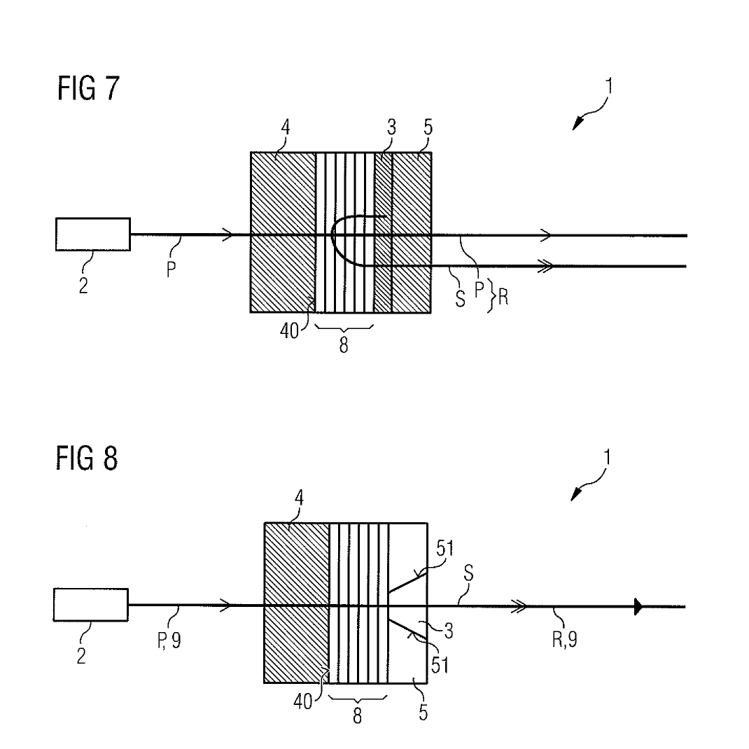

In the exemplary embodiment according to FIG. 7 a coating 8 is applied to the major side 40 of the first carrier 4, which coating 8 constitutes a Bragg mirror. The coating 8 is transmissive relative to the primary radiation P and highly reflective relative to the secondary radiation S. The radiation R emitted by the light source is a mixture of primary radiation P and secondary radiation S. For better heat dissipation from the conversion medium 3, the latter is again located between the first carrier 4 and the second carrier 5.

In the exemplary embodiment according to FIG. 8 the second carrier 5 comprises a frustoconical recess, in which the conversion medium 3 is located. Side walls 51 of the second carrier 5 are reflective relative to the secondary radiation S. The second carrier 5 is made for example of solid metal.

In contrast to what is shown in FIG. 8, the side walls 51 may be paraboloidal in shape, such that reflection of the secondary radiation S at the side walls 51 may result in a parallel pencil of rays. The side walls 51 may be rotationally symmetrical relative to a beam path 9. The beam path 9 is defined by the main beam directions of the primary radiation P and the radiation R emitted by the light source 1.

FIG. 9 shows an exemplary embodiment in which the first carrier 4 is lenticular. In this way the secondary radiation S is deflected at a curved outer surface of the first carrier 4 remote from the conversion medium 3 towards an optical axis and towards the beam path 9. For additional collimation the light source 1 comprises a lens 17 in the form of a concavo-convex lens. Refraction of the secondary radiation S at the boundary surfaces of the lens 17 and the first carrier 4 is shown only schematically in FIG. 9.

In contrast to what is shown in FIG. 9, the major side 40, facing the semiconductor laser 2, of the first carrier 4 may also be curved rather than flat. It is likewise possible for the conversion medium 3 to be located in a recess, not shown, in the first carrier 4.

In the exemplary embodiment according to FIG. 10, three different conversion media 3a-c, which are applied to the carriers 4 in each case in a small region, are supplied with the primary radiation P from a single semiconductor laser 2 via light guides. The arrangement of conversion media 3a-c, carriers 4, collimating optical systems 6 and filters 15a—c may be configured as in the exemplary embodiment according to FIG. 2 for instance.

The conversion media 3a-c are designed to generate red, green and blue light. The filters 15a-c are designed in each case to transmit a spectral range of the secondary radiation S emitted by the respective conversion medium 3a-c. The filters 15a-c are impermeable to the primary radiation P. The radiation R emitted by the light source 1 is a mixture of the secondary radiations Sa-c.

In the exemplary embodiment of the light source 1 according to FIG. 11, said light source comprises three semiconductor lasers 2a-c, which generate three different primary radiations Pa-c. The three secondary radiations Sa-c, which have different wavelengths, are generated by means of three different conversion media 3a-c. The radiation R emitted by the light source 1 is mixed radiation comprising these three secondary radiations Sa-c.

It is possible for the semiconductor lasers 2a-c to emit at slightly different wavelengths, such that the different conversion media 3a-c may be efficiently optically pumped. Alternatively, the semiconductor lasers 2a—c may be identical semiconductor lasers, so simplifying actuation or energisation of the semiconductor lasers 2a-c.

FIG. 12 shows a light source 1 in which four semiconductor lasers 2 are coupled via lenses 17 into an optical fibre and together irradiate the light spot 7 of the conversion medium 3, in order to achieve particularly high luminance of the secondary radiation S.

According to FIG. 13 the light source 1 comprises a modulator 11. The modulator 11 takes the form for example of a liquid crystal mask, a spatial light modulator, a Kerr cell or a Pockels cell. By way of reflection or transmission, the modulator 11 may in particular adjust the intensity of the primary radiation P or the secondary radiation S. Preferably, the modulator 11 may be tuned to or operated at frequencies of at least 10 MHz, in particular of at least 25 MHz.

According to FIG. 13A the modulator 11 is located in the beam path of the primary radiation P between the semiconductor laser 2 and the conversion medium. According to FIG. 13B the modulator 11 is mounted in the beam path of the secondary radiation S between the collimating optical system 6 and the carrier 4.

FIG. 13C shows that the modulator 11 is integrated into an optical fibre, which is designed to convey the pump radiation P from four semiconductor lasers 2 to the conversion medium 3.

The modulator 11 may also be located, see FIG. 13D, downstream of the filter 15 in the beam path, such that the mixed radiation consisting of the primary radiation P and the secondary radiation S may be modulated.

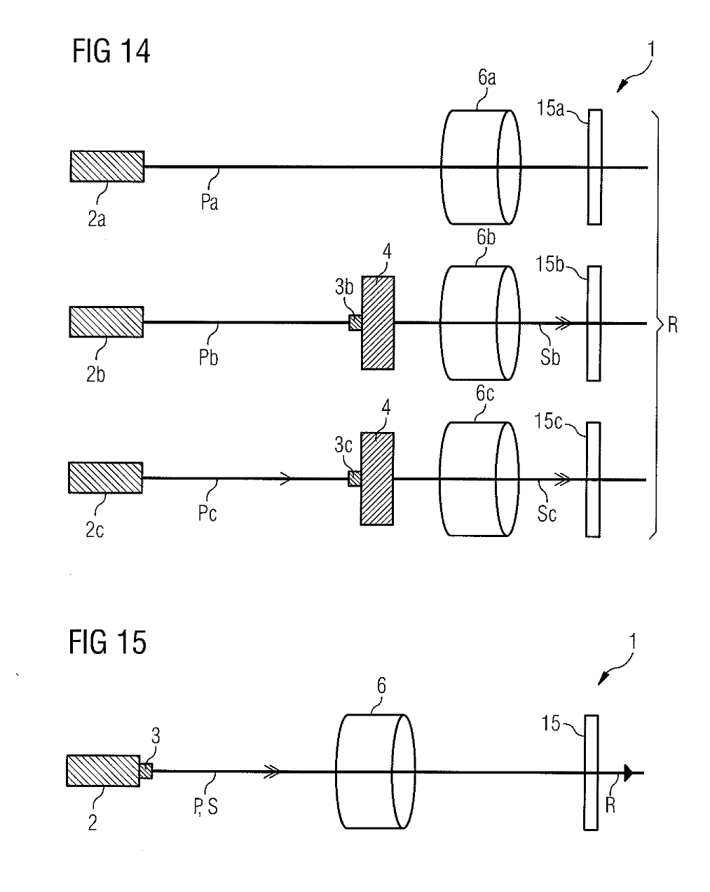

In the exemplary embodiment according to FIG. 14 the light source 1 comprises three identical semiconductor lasers 2a-c. The primary radiations Pa-c have wavelengths in the blue spectral range. The primary radiations Pb, Pc are converted by the conversion media 3b, 3c into the green secondary radiation Sb and the red secondary radiation Sc. Conversion of the primary radiation Pa does not occur. The radiation R emitted by the light source 1 is then a mixture of the primary radiation Pa and the secondary radiations Sb, Sc.

FIG. 15 shows an exemplary embodiment of the light source 1 in which the conversion medium 3 is applied directly to the semiconductor laser 2. This may have the consequence in particular of the conversion medium 3 being thermally coupled to the semiconductor laser 2.

FIG. 16 shows an exemplary embodiment of a projector 10. Three light sources 1a-c emit the red, green and blue secondary radiation Sa-c. The secondary radiations Sa-c are directed onto the common beam path 9 by way of mirrors 18a-c, which may take the form of dichroic mirrors and comprise for example a plurality of dielectric layers. The common beam path 9 has located in it the modulator 11, by means of which the intensity of the secondary radiations Sa-c and the colour location of the radiation R emitted by the light source 1 may be modulated to a high frequency.

A deflection unit 13 is arranged downstream of the modulator 11, which deflection unit may consist of a spatial light modulator or a rapidly movable mirror. By way of the deflection unit 13 the radiation R, in the form of an approximately parallel pencil of rays, is deflected and passed rapidly over a projection surface 19, on which an image then appears. The projector 10 according to FIG. 16 thus in particular comprises a “Flying Spot Projector”.

As an alternative to the illustration according to FIG. 16, it is likewise possible for three different modulators 11 in each case to be located for example in the beam paths of the secondary radiations Sa-c.

The projector 10 according to FIG. 17 has an imaging unit 14, which is arranged downstream of the modulator 11 in the common beam path 9. The imaging unit 14 may comprise a liquid crystal mask or a digital micromirror device, DMD for short. Downstream of the imaging unit 14 a lens 17 is arranged which images the radiation R emitted by the light source 1 or by the projector 10 onto the projection surface 19. The lens 17 may also comprise a lens system.

The light source 1 according to FIG. 18 comprises a single conversion medium 3, which is applied over a small region 41 of the carrier 4. A collimating optical system 6 is arranged downstream of the conversion medium 3. Downstream of the collimating optical system 6 in the beam direction is located the deflection unit 13. The deflection unit 13 may be a mobile mirror or indeed an optical fibre. The deflection unit 13 subdivides the secondary radiation S into the secondary radiations Sa-c. These secondary radiations Sa-c may in each case be white light or indeed spectrally subdivided red, green and blue light. Imaging units 14a-c and/or filters 15 are optionally arranged downstream of each of the secondary radiations Sa-c. The radiation R emitted by the light source 1 is composed of the secondary radiations Sa-c, which have passed through the filters 15 and/or the imaging units 14a-c.

In the exemplary embodiment according to FIG. 19 the carrier 4 is mounted in mobile manner. In other words, the carrier 4, onto which the three regions 41a-c with the in particular mutually different conversion media 3a-c are applied, may be displaced and positioned in a direction perpendicular to the beam path 9. The conversion media 3a-c may exhibit different thicknesses in a direction perpendicular to the major side 40. The direction of movement of the first carrier 4 is indicated by a double-headed arrow.

By displacing the first carrier 4 in a direction perpendicular to the beam path 9, it is possible for different regions 41a-c and thus different conversion media 3a-c to be irradiated by the primary radiation P as a function of the position of the first carrier 4. The colour location and/or the intensity of the radiation R emitted by the light source 1 may thus be set as a function of the position of the first carrier.

According to FIG. 19A green light is generated, for example, while according to FIG. 19B red light and according to FIG. 19C blue light are for example generated. By way of the filter 15, which may optionally be mounted downstream of the collimating optical system 6, the colour location of the radiation R emitted by the light source 1 may be further restricted.

The light source 1 according to FIG. 19 may be used for example in a laser pointer, which emits in different colours as a function of the position of the first carrier. In this case the first carrier 4 is held for example in three positions, which may each be set for example by snapping the first carrier 4 into place. While the light source 1 is emitting the radiation R, the position of the first carrier 4 is preferably not changed.

It is likewise possible for the first carrier 4 to move comparatively quickly, such that the conversion media 3a-c are irradiated alternately in quick succession by the primary radiation P. This for example reduces the thermal loading to which the conversion media 3a-c are exposed as a result of the conversion of the primary radiation P. If the first carrier 4 moves quickly, for example by rotation, the light source 1 may for instance be used in a projector. In this case, a modulator, not shown in FIG. 19, is located in particular between the semiconductor laser 2 and the first carrier 4 with the conversion media 3a-c.

In the exemplary embodiment according to FIG. 20 the semiconductor laser 2, of which there is in particular precisely one, is located completely in a housing 20. The housing 20 may be a surface-mountable housing, for example an SMT solderable housing. The housing 20 may also take the form of a “Transistor Single Outline housing”, TO housing for short. The housing 20 is fastened, for example by soldering or electrically conductive adhesive bonding, to a body 21 not belonging to the light source 1. The fastening of the housing 20 to the body 21, which may take the form in particular of a heat sink or printed circuit board, preferably also results in electrical interconnection of the light source 1.

The semiconductor laser 2 emits the primary radiation P with a relatively large divergence angle in a direction parallel to a major side 23 of the body 21. The primary radiation P is symbolised by lines with arrow heads. The primary radiation P is then deflected via a prism 22 into a direction perpendicular to the major side 23. The prism 22 acts for example by way of total reflection or by way of a reflective coating, not shown, on the side facing the semiconductor laser 2.

Downstream of the prism 22 in the beam direction is the conversion medium 3, which is applied in a layer to the first carrier 4 on a side facing the semiconductor laser 2. The first carrier 4 preferably has a transmissive action relative to the secondary radiation S not shown in FIG. 20 and either a transmissive or an impermeable action relative to the primary radiation P.

In regions of the first carrier 4 in which no conversion medium 3 is applied, there is located the material of the perforated diaphragm 12. It is in this way ensured that radiation passes out of the light source 1 only in the region in which the conversion medium 3 is located.

In the exemplary embodiment according to FIG. 21, the lens 17 is mounted between the prism 22 and the semiconductor laser 2. The lens 17 makes it possible to focus the primary radiation P into the conversion medium 3.

According to FIG. 21 the housing 20 is in one piece, consisting for example of a plastics main body. The housing 20 may likewise be composed of a plurality of parts.

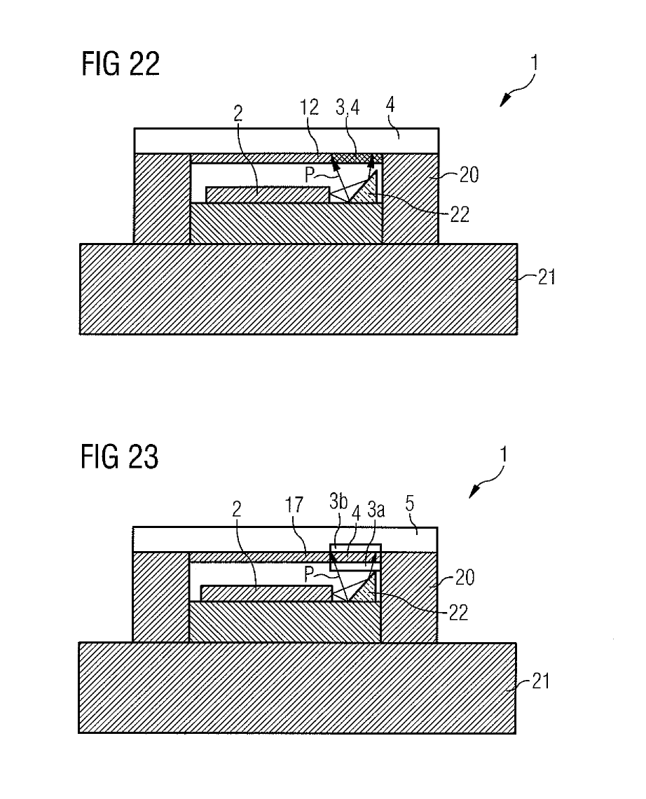

FIG. 22 shows that the conversion medium 3 may be embedded in a matrix material. The matrix material is preferably made of the same material as the first carrier 4. In particular, conversion medium 3 and first carrier 4 may thereby be made in one piece. The conversion medium 3 and the material of the first carrier 4 may for example be combined or connected together by means of a common sintering process.

As can be seen from FIG. 23, the conversion medium 3a, b is applied to both sides of the first carrier 4. The first carrier 4 may be a thin, transparent ceramic plate. The first carrier 4 with the conversion media 3a, b is applied to the second carrier 5. The conversion media 3a, b and the first carrier 4 may optionally be introduced completely or in part into a recess in the second carrier 5. The conversion media 3a, 3b may contain identical or different luminescent materials.

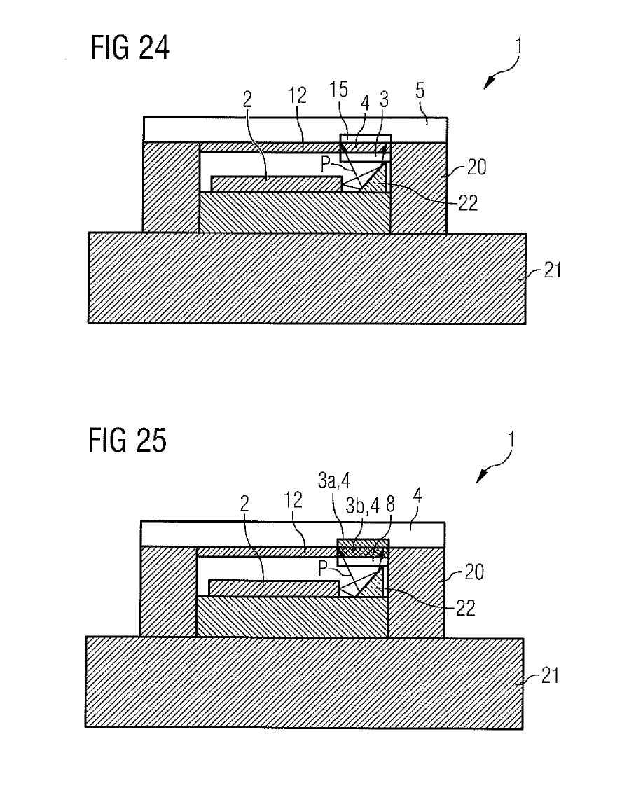

In the exemplary embodiment according to FIG. 24, in which the first carrier 4 is likewise for example a ceramic wafer, the conversion medium 3 is applied to one side of the first carrier 4 and the filter 15 is applied in layers to the side remote from the conversion medium 3 and the semiconductor laser 2. It is optionally possible for the second carrier 5 to comprise an admixture of pigments, particles or dyes, such that the second carrier 5 may assume the function of the filter 15.

The light source 1 according to FIG. 25 comprises two different conversion media 3a, b. The conversion media 3a, b are embedded into the heat-conducting matrix material of the first carrier 4. This results in efficient heat conduction away from the conversion medium 3. In contrast to what is shown in FIG. 25, it is also possible, for example, for the conversion medium 3b to be embedded in a matrix material from which the second carrier 5 is formed.

Between the conversion media 3a, b and the first carrier 4 on the one hand and the prism 22 on the other hand there is located the coating 8. The coating 8 has a transmissive action relative to the primary radiation P and a reflective action relative to the secondary radiation S not shown in FIG. 25, so improving the efficiency with which the secondary radiation S is coupled out of the light source 1.

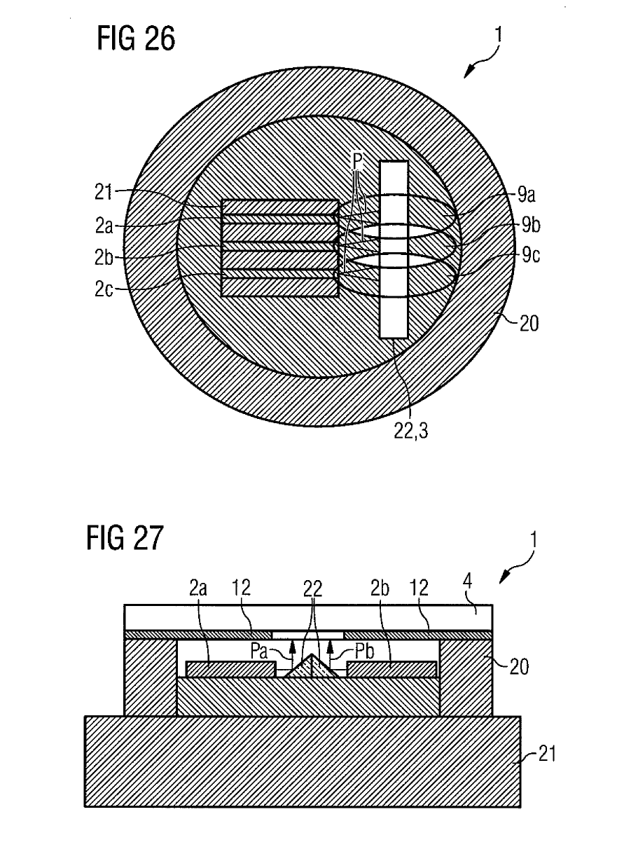

FIG. 26 shows a plan view of the light source 1 for instance according to one of FIGS. 20 to 25. The housing 20 has a circular outline. In a circular recess there are located the three semiconductor lasers 2a-c, which emit the primary radiation P. The primary radiation P is directed onto the conversion medium 3 by way of the prism 22 and converted into the secondary radiations Sa-c, which leave the light source 1 in a direction perpendicular to the plane of the drawing.

The semiconductor lasers 2a-c may be of identical or indeed different construction. It is possible for the semiconductor lasers 2a-c to be placed directly on the body 21 and electrically contacted directly thereto.

In the light source 1 according to FIG. 27 the semiconductor lasers 2a, 2b are arranged such that they emit the primary radiations Pa, b antiparallel. The primary radiations Pa, b are deflected by way of the two prisms 22 towards the conversion medium 3.

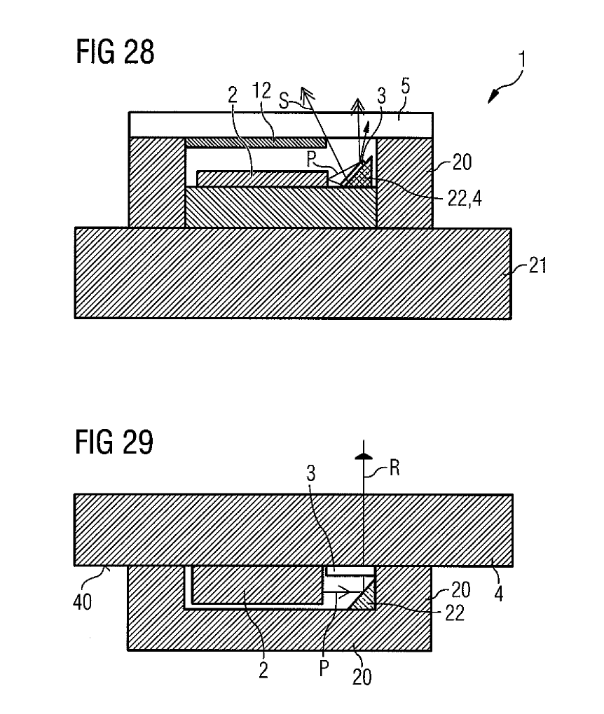

In the exemplary embodiment according to FIG. 28 the conversion medium 3 is applied to the prism 22, which at the same time forms the first carrier 4. The side of the prism 22 which faces the semiconductor laser 2 and to which the conversion medium 3 is applied has a reflective action relative both to the primary radiation P and the secondary radiation S. In this way the layer thickness of the conversion medium 3 may be reduced, since the primary radiation P effectively detects a double layer thickness of the conversion medium 3 due to the reflection at the prism 22. The second carrier 5 is for example impermeable relative to the primary radiation P and transmissive relative to the secondary radiation S. The second carrier 5 is preferably transparent relative to the secondary radiation S and for instance provided with antireflective coatings, not shown in FIG. 28.

In the exemplary embodiment according to FIG. 29 both the semiconductor laser 2 and the conversion medium 3 are applied directly to the first carrier 4. The primary radiation P is deflected by way of the prism 22 mounted on the housing 20 towards the conversion medium 3 and the first carrier 4. The radiation R emitted by the light source 1 passes through the transparent, thermally conductive first carrier 4. Electrically conductive tracks for supplying power to the semiconductor laser 2 are for example applied to the major side 40 of the first carrier 4. A perforated diaphragm, not shown in FIG. 29, may optionally be mounted on the carrier 4.

The invention described herein is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

This patent application claims priority from German patent application 10 2008 063 634.7, whose disclosure content is hereby included by reference.

1.-15. (canceled)

16. A light source comprising:
at least one semiconductor laser, which is designed to emit primary radiation of a wavelength of between 360 nm and 485 nm inclusive; and
at least one conversion medium, which is arranged downstream of the semiconductor laser and is designed to convert at least part of the primary radiation into secondary radiation of a different, greater wavelength than the primary radiation,
wherein the radiation emitted by the light source has an optical coherence length which amounts to at most 50 μm.

17. The light source according to claim 16, wherein the luminance of the secondary radiation on exit from the conversion medium amounts at least in places to at least 1 kW/cm².

18. The light source according to claim 16, further comprising a thermally conductive first carrier, on which the conversion medium is mounted at least indirectly and which is transparent or reflective for at least part of the secondary radiation, and which is transparent or impermeable for the primary radiation.

19. The light source according to claim 16, further comprising at least one collimating optical system, which is arranged downstream of the conversion medium, the divergence angle of the secondary radiation amounting, after passage through the collimating optical system, at least in places to at most 10°.

20. The light source according to claim 16, wherein at least one light spot of the conversion medium which is irradiated by the primary radiation has an area of at most 0.5 mm².

21. The light source according to claim 16, comprising at least two semiconductor lasers which are configured to irradiate the same light spot.

22. The light source according to claim 16, further comprising a second carrier, wherein the conversion medium is located between the first carrier and a second carrier and is in each case in at least indirect contact with the carriers, the primary radiation passing through at least one of the carriers.

23. The light source according to claim 16, wherein a major side of the first carrier, to which the conversion medium is applied, is reflective at least relative to the secondary radiation or is provided with a reflective coating, and wherein the direction of a beam path is modified by the first carrier.

24. The light source according to claim 16, comprising at least three semiconductor lasers, at least two of the semiconductor lasers irradiating at least two different light spots of the at least one conversion medium, and the radiation emitted by the light source comprising red, green and blue light.

25. The light source according to claim 24, wherein the red, green and blue light can be generated mutually independently and pass jointly along at least part of the beam path.

26. The light source according to claim 16, further comprising at least one modulator, which is located in the beam path of the secondary radiation and which is designed to adjust the intensity of the secondary radiation by way of transmission or reflection.

27. The light source according to claim 16, wherein an intensity and/or a chromaticity coordinate of the radiation emitted by the light source can be tuned to a frequency of at least 10 MHz.

28. The light source according to claim 16, wherein the first carrier is mounted so as to be mechanically mobile and comprises at least two regions which are provided with mutually different conversion media, such that a chromaticity coordinate of the secondary radiation can be set by moving the first carrier.

29. A light source according to claim 16, wherein the first carrier displays thermal conductivity of at least 40 W/(m K), wherein at least one pinhole is arranged downstream of the conversion medium or the conversion medium is mounted on a region of the first carrier which has a diameter which corresponds to at most three times the average diameter of the light spot, and
wherein the light source comprises a deflection unit and/or an imaging unit which is located in or on the beam path.

30. A projector comprising at least one light source according to claim 16, and further comprising at least one deflection unit and/or at least one imaging unit.
